(19) United States
(12) Patent Application Publication
(10) Pub. No.: US 2018/0151380 A1
(43) Pub. Date: May 31, 2018

(54) SUBSTRATE PROCESSING APPARATUS AND HEAT SHIELD PLATE

(71) Applicant: TOKYO ELECTRON LIMITED, Tokyo (JP)

(72) Inventors: Hiroyuki OGAWA, Nirasaki City (JP); Akitaka SHIMIZU, Nirasaki City (JP); Shigeki DOBA, Nirasaki City (JP)

(21) Appl. No.: 15/822,658

(22) Filed: Nov. 27, 2017

(30) Foreign Application Priority Data
Nov. 28, 2016 (JP) 2016-230544

(51) Int. Cl. H01L 21/3065

(52) U.S. Cl. CPC H01L 21/3065; H01J 2237/334; H01J 2237/3174

(57) ABSTRACT

There is provided a substrate processing apparatus which includes: a process container configured to accommodate a substrate; a partition member disposed between plasma generated inside the process container and the substrate, the partition member configured to selectively transmit radicals in the plasma toward the substrate; and a heat shield plate disposed between the partition member and the substrate. The heat shield plate is disposed so as to face the substrate. The heat shield plate is made of metal or silicon and is connected to the process container.

### CROSS-REFERENCE TO RELATED APPLICATION

This application is based upon and claims the benefit of priority from Japanese Patent Application No. 2016-230544, filed on Nov. 28, 2016, the entire contents of which are incorporated herein by reference.

### TECHNICAL FIELD

The present disclosure relates to a substrate processing apparatus of processing a substrate using radicals in plasma and a heat shield plate applied to the substrate processing apparatus.

### BACKGROUND

In recent years, it has been proposed to subject a semiconductor wafer (hereinafter simply referred to as “wafer”) as a substrate to a chemical etching process using radicals in plasma.

An apparatus for performing such a chemical etching process includes a plate-like ion trap interposed between the plasma and the wafer in a process container and configured to suppress the movement of ions in the plasma toward the wafer. The ion trap has a plurality of slits formed to penetrate through the ion trap in the thickness direction. A labyrinth composed of the plurality of slits blocks the movement of anisotropically-moving ions while allowing the transmission of isotropically-moving radicals. As a result, it is just about only the radicals that exist in a process space facing the wafer. The radicals and a process gas introduced into the process space react with a surface layer of the wafer, whereby the wafer is subjected to a chemical etching process.

In general, a plasma distribution is susceptible to the form of a magnetic field or an electric field. For example, when a process container has a cylindrical shape, the concentration of plasma tends to increase near the central axis of the process container. Therefore, in the ion trap facing the plasma, many ions collide with the central portion of the ion trap. For example, when the chemical etching process is repeated, much heat accumulates in the central portion of the ion trap. As a result, the amount of radiant heat radiated from the central portion of the ion trap toward the process space or the wafer increases.

Incidentally, a distribution of radicals is strongly influenced by the heat distribution. Therefore, if the amount of radiant heat radiated from the central portion of the ion trap increases due to the repetition of the chemical etching process and if a deviation of the heat distribution occurs in the process space, such a deviation is also generated in the distribution of the radicals in the process space. This causes a problem in which the chemical etching process cannot be uniformly performed with respect to the wafer.

### SUMMARY

Some embodiments of the present disclosure provide a substrate processing apparatus and a heat shield plate which are capable of uniformly processing a substrate using radicals even if such a process is repeated.

According to one embodiment of the present disclosure, there is provided a substrate processing apparatus which includes: a process container configured to accommodate a substrate; a partition member disposed between plasma generated inside the process container and the substrate, the partition member configured to selectively transmit radicals in the plasma toward the substrate; and a heat shield plate disposed between the partition member and the substrate, wherein the heat shield plate is disposed so as to face the substrate, the heat shield plate being made of metal or silicon and being connected to the process container.

According to another embodiment of the present disclosure, there is provided a heat shield plate disposed between a partition member, which is disposed between plasma and a substrate and configured to selectively transmit radicals in the plasma toward the substrate, and the substrate, wherein the heat shield plate is disposed so as to face the substrate, and the heat shield plate is made of metal or silicon.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a plan view schematically showing a configuration of a substrate processing system including a substrate processing apparatus according to an embodiment of the present disclosure.

FIG. 2 is a sectional view schematically showing a configuration of a process module for executing a COR process in FIG. 1.

FIGS. 3A and 3B are views schematically showing a configuration of a partition plate in FIG. 2, FIG. 3A being a view of the partition plate as viewed from a substrate process space, and FIG. 3B being a sectional view taken along line in FIG. 3A.

FIGS. 4A and 4B are views schematically showing a configuration of a heat shield plate in FIG. 2, FIG. 4A being a view of the heat shield plate as viewed from a substrate process space, and FIG. 4B being a sectional view taken along line IV-IV in FIG. 4A.

FIGS. 5A and 5B are views schematically showing a configuration of a modification of the heat shield plate shown in FIGS. 4A and 4B, FIG. 5A being a view of the heat shield plate as viewed from a substrate process space, and FIG. 5B being a sectional view taken along line V-V in FIG. 5A.

FIG. 6 is a graph showing a time-dependent change in temperature of the partition plate and the wafer when a COR process is repeated in a process module not including a heat shield plate.

FIG. 7 is a graph showing a time-dependent change in temperature of the partition plate and the wafer when a COR process is repeated in a process module including a heat shield plate.

### DETAILED DESCRIPTION

Hereinafter, embodiments of the present disclosure will be described in detail with reference to the drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

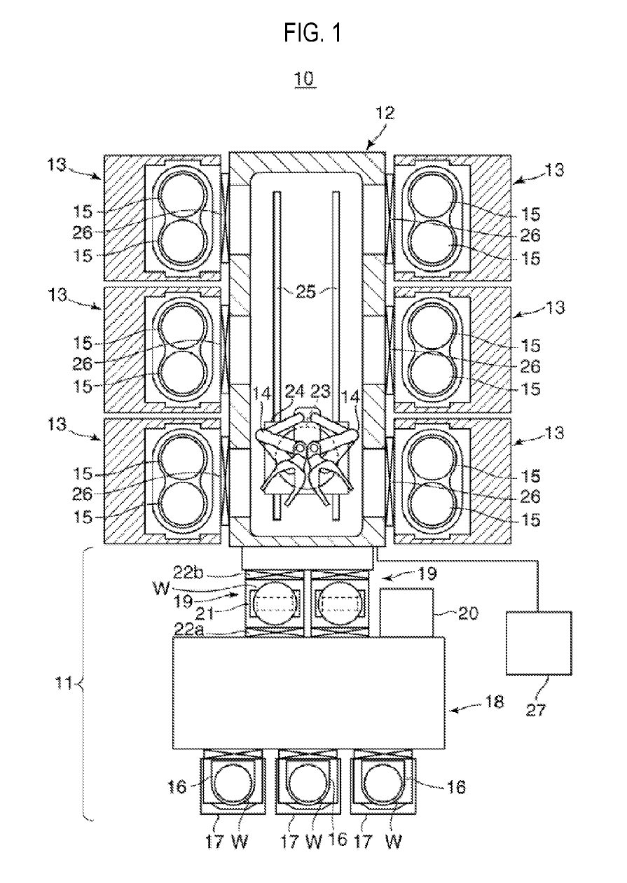

FIG. 1 is a plan view schematically showing a configuration of a substrate processing system including a substrate processing apparatus according to an embodiment of the present disclosure. In FIG. 1, in order to facilitate understanding, a portion of an internal configuration is shown in a see-through manner.

Referring to FIG. 1, a substrate processing system 10 includes a wafer storage part 11 configured to store a plurality of wafers W, a transfer module 12 serving as a transfer chamber that simultaneously transfers two sheets of wafers W, and a plurality of process modules 13 (substrate processing apparatuses) configured to perform a COR (Chemical Oxide Removal) process, a PHT (Post Heat Treatment) process or a film forming process with respect to the wafers W loaded from the transfer module 12. The interior of each of the process modules 13 and the interior of the transfer module 12 are maintained in a vacuum atmosphere.

In the substrate processing system 10, the wafers W stored in the wafer storage part 11 are transferred by transfer arms 14 built in the transfer module 12 and are mounted one by one on each of two stages 15 arranged inside each of the process modules 13. Subsequently, in the substrate processing system 10, the respective wafers W mounted on the stages 15 are subjected to the COR process, the PHT process or the film forming process by the respective process modules 13. Thereafter, the processed wafers W are unloaded to the wafer storage part 11 by the transfer arms 14.

The wafer storage part 11 includes a plurality of load ports 17 each serving as a mounting stand of a FOUP 16 which is a container for storing the plurality of wafers W, a loader module 18 configured to receive the stored wafers W from the FOUP 16 mounted on each of the load ports 17 or to hand over the wafers W subjected to a predetermined process in the process module 13 to the FOUP 16, two load lock modules 19 configured to temporarily hold the wafers W in order to deliver the wafers W between the loader module 18 and the transfer module 12, and a cooling storage 20 configured to cool the wafers W subjected to the PHT process.

The loader module 18 is composed of a rectangular housing whose interior is kept in an atmospheric pressure atmosphere. The plurality of load ports 17 is juxtaposed at one side surface constituting the long side of the rectangular housing. Further, the loader module 18 is provided therein with a transfer arm (not shown) which is movable in the longitudinal direction of the rectangular housing. The transfer arm loads the wafers W into the load lock module 19 from the FOUP 16 mounted on each of the load ports 17 or unloads the wafers W from the load lock module 19 to the respective FOUP 16.

Each of the load lock modules 19 temporarily holds the wafers W so that the wafers W accommodated in the FOUP 16 mounted on each load port 17 kept in an atmospheric pressure atmosphere are handed over to the process module 13 whose interior is kept in a vacuum atmosphere. Each of the load lock modules 19 includes a buffer plate 21 that holds two sheets of wafers W. Each of the load lock modules 19 includes a gate valve 22a for securing airtightness against the loader module 18 and a gate valve 22b for securing airtightness with respect to the transfer module 12. Furthermore, a gas introduction system and a gas exhaust system (both not shown) are connected to each of the load lock modules 19 through respective pipes. The interior of the load lock module 19 is controlled to be kept in an atmospheric pressure atmosphere or a vacuum atmosphere.

The transfer module 12 loads unprocessed wafers W from the wafer storage part 11 into the process module 13, and unloads processed wafers W from the process module 13 to the wafer storage part 11. The transfer module 12 is composed of a rectangular housing whose interior is kept in a vacuum atmosphere. The transfer module 12 includes two transfer arms 14 that hold and move two sheets of wafers W, a rotary stand 23 that rotatably supports each of the transfer arms 14, a rotatable mounting table 24 on which the rotary stand 23 is mounted, and a guide rail 25 configured to guide the rotatable mounting table 24 in the longitudinal direction of the transfer module 12. In addition, the transfer module 12 is connected to each of the load lock modules 19 of the wafer storage part 11 and each of the process modules 13 via the respective gate valves 22b and 26 (to be described later). In the transfer module 12, the transfer arms 14 load two wafers W from the load lock module 19 into each process module 13, and unloads two processed wafers W from each process module 13 to another process module 13 or the load lock module 19.

In the substrate processing system 10, each process module 13 executes one of the COR process, the PHT process and the film forming process. In addition, operations of the respective parts of the substrate processing system 10 are controlled by an apparatus controller 27 according to a predetermined program.

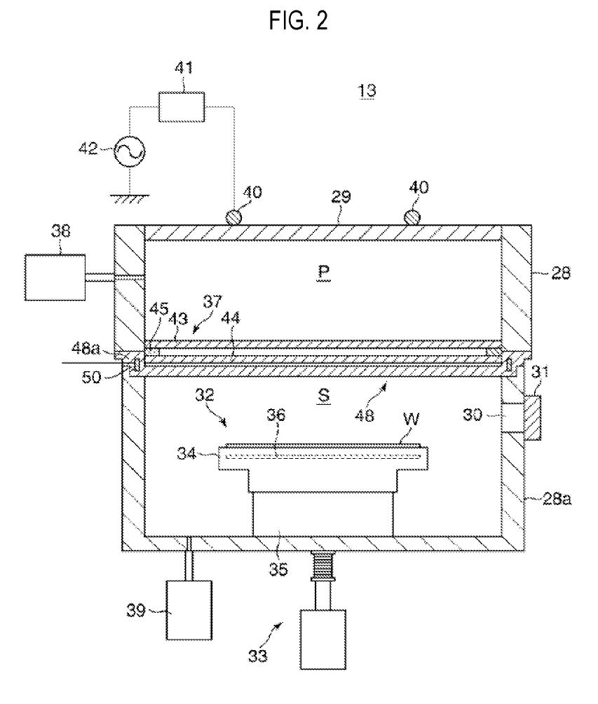

FIG. 2 is a sectional view schematically showing the configuration of the process module for executing the COR process in FIG. 1.

Referring to FIG. 2, the process module 13 for performing the COR process includes a process container 28 having a hermetically sealed structure, which is configured to accommodate the wafers W. The process container 28 is made of, for example, aluminum or aluminum alloy. An upper end of the process container 28 is opened or closed by a lid 29 serving as a ceiling portion. A loading/unloading port 30 through which the wafer W is transferred is formed in a side wall portion 28a of the process container 28. The loading/unloading port 30 can be opened and closed by a gate valve 31.

Furthermore, the process module 13 includes a mounting table 32 disposed in the inner bottom surface of the process container 28 and configured to mount the wafer W thereon in a horizontal posture, and an elevating mechanism 33 configured to raise or lower the mounting table 32. The mounting table 32 has a substantially columnar shape and includes a mounting plate 34 on which the wafer W is directly mounted and a base block 35 configured to support the mounting plate 34. A temperature adjusting mechanism 36 for controlling the temperature of the wafer W is installed inside the mounting plate 34. The temperature adjusting mechanism 36 includes, for example, a conduit (not shown) through which a temperature adjusting medium (e.g., water) circulates. The temperature adjusting mechanism 36 adjusts the temperature of the wafer W by allowing heat exchange between the temperature adjusting medium flowing through the conduit and the wafer W. The elevating mechanism 33 is disposed outside the process container 28, and includes an actuator or the like for raising and lowering the mounting table 32. In addition, a plurality of lift pins (not shown) used when loading and unloading the wafer W into and out of the process container 28 is installed in the mounting table 32 so as to be moved upward and downward on the upper surface of the mounting plate 34.

The interior of the process container 28 is divided into a plasma generation space P defined as an upper portion and a substrate process space S defined as a lower portion by a partition plate 37 (to be described later). The plasma generation space P is a space where plasma is generated. The substrate process space S is a space where a COR process is performed on the wafer W. A gas supply source 38 and another gas supply source (not shown) are installed outside the process container 28. These gas supply sources are configured to supply a process gas composed of a fluorine-containing gas (e.g., an NF₃ gas), a hydrogen-containing gas (e.g., an NH₃ gas) and a dilution gas such as an Ar gas or an N₂ gas into the process container 28. In the present embodiment, NH₄F as an etchant is generated from the process gas. The NH₄F thus generated is adsorbed onto the surface of the wafer W so that the SiO₂ film on the surface of the wafer W reacts with the etchant, thereby generating AFS (ammonium fluosilicate) which is a reaction product. However, when an NH₃ gas is turned into plasma, the NH₄F as an etchant is not generated. Furthermore, in the process module 13, as will be described later, plasma is generated from the process gas in the plasma generation space P. However, when an NF₃ gas is turned into plasma, F radicals (F*, NF₂*) in a high energy state are positively generated (NF₃+e→F*, NF₂*). Thus, in the process module 13, the NH₃ gas is directly supplied to the substrate process space S without going through the plasma generation space P, and the NF₃ gas is supplied to the plasma generation space P so as to be turned into plasma. Therefore, in the present embodiment, the gas supply source 38 mainly supplies the NF₃ gas to the plasma generation space P, and another gas supply source mainly supply the NH₃ gas directly to the substrate process space S. In addition, the process module 13 includes an exhaust mechanism 39. The exhaust mechanism 39 includes a vacuum pump to discharge the gas existing in the substrate process space S outside of the process container 28.

Furthermore, the process module 13 is configured as an inductively-coupled plasma etching apparatus using an RF antenna. The lid 29 serving as the ceiling portion of the process container 28 is formed of, for example, a circular quartz plate and is configured as a dielectric window. An annular RF antenna 40 for generating inductively-coupled plasma in the plasma generation space P of the process container 28 is formed on the lid 29. The RF antenna 40 is connected to a high-frequency power source 42 via a matcher 41. The high-frequency power source 42 outputs, at an arbitrary output value, the high frequency power of a constant frequency (usually 13.56 MHz or more) suitable for generation of plasma by inductively-coupled high frequency discharge. The matcher 41 includes a reactance-variable matching circuit (not shown) for matching the impedance at the side of the high-frequency power source 42 and the impedance at the side of a load (the RF antenna 40 or the plasma). The generation of the inductively-coupled plasma in the plasma generation space P using the RF antenna 40 will be described later.

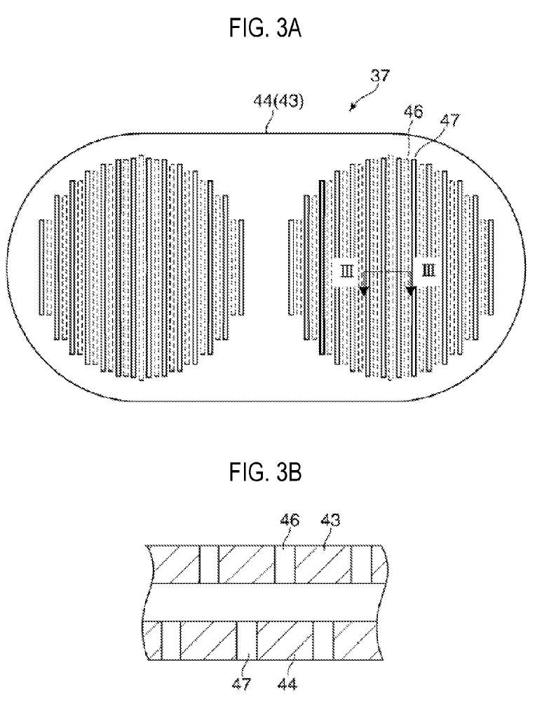

FIGS. 3A and 3B are views schematically showing a configuration of a partition plate in FIG. 2. FIG. 3A is a view of the partition plate as viewed from the substrate process space, and FIG. 3B is a sectional view taken along line in FIG. 3A.

As shown in FIGS. 3A and 3B, the partition plate 37 includes at least two substantially elliptical plate-like members 43 and 44. The reason why the plate-like members 43 and 44 have a substantially elliptical shape is that the horizontal sectional shape of the process container 28 of the process module 13 has a substantially elliptical shape as shown in FIG. 1. The shape of the plate-like members 43 and 44 is not limited to the substantially elliptical shape, but may vary depending on the horizontal sectional shape of the process container 28. The plate-like members 43 and 44 are arranged so as to be superimposed from the plasma generation space P toward the substrate process space S. A spacer 45 for maintaining a gap between the plate-like members 43 and 44 at a predetermined value is disposed between the plate-like members 43 and 44. A plurality of slits 46 and 47 penetrating in the overlapping direction is formed in the plate-like members 43 and 44, respectively. The slits 46 formed in the plate-like member 43 are arranged in parallel with each other, and the slits 47 formed in the plate-like member 44 are also arranged in parallel with each other. In addition, when viewing the partition plate 37 from the substrate process space S, the slits 46 are arranged so as not to overlap with the slits 47. In each of the plate-like members 43 and 44, the respective slits 46 and 47 may be formed in a lattice shape. Even in this case, when viewing the partition plate 37 from the substrate process space S, the slits 46 are arranged so as not to overlap with the slits 47. Instead of respective slits 46 and 47, a plurality of through-holes may be formed in each of the plate-like members 43 and 44. The plate-like members 43 and 44 are made of, for example, quartz glass. Furthermore, the spacer 45 is made of, for example, quartz. Alternatively, the spacer 45 may be made of aluminum (Al), silicon (Si) or yttrium compound (Y₂O₃ or YF₃).

In the process module 13, the partition plate 37 functions as a so-called ion trap for suppressing ions in the plasma from being transferred from the plasma generation space P to the substrate process space S when the inductively-coupled plasma is generated in the plasma generation space P. Specifically, the slit arrangement structure in which each slit 46 is disposed so as not to overlap with each slit 47, namely the labyrinth structure, prevents the movement of anisotropically moving ions while allowing isotropically moving radicals to be transmitted through the partition plate 37. Accordingly, only the radicals are selectively transmitted to the substrate process space S, thereby reducing the possibility of the presence of ions in the substrate process space S. If the possibility that ions are present in the substrate process space S is reduced, it is possible to reduce the damage that may be caused by collision of ions against the wafer W. The partition plate 37 blocks vacuum ultraviolet light emitted from the plasma and prevents the surface layer of the wafer W from being deteriorated by the vacuum ultraviolet light.

In the process module 13, when performing a COR process on the wafer W, the gate valve 31 is first opened, and the wafer W to be processed is loaded into the process container 28 and mounted on the stage 32. Subsequently, with the gate valve 31 closed, the process gas is supplied from the gas supply source 38 and another gas supply sources to the plasma generation space P and the substrate process space S. Further, an internal pressure of the process container 28 is set to a predetermined value by the exhaust mechanism 39. Moreover, a high frequency power for plasma generation is outputted from the high-frequency power source 42 at a predetermined output value to generate a high frequency current in the RF antenna 40.

If the high frequency current is generated in the RF antenna 40, magnetic force lines (magnetic fluxes) penetrate the lid 29 and move across the plasma generation space P, whereby an induced electric field flowing in the azimuthal direction is generated inside the plasma generation space P. Electrons accelerated in the azimuth direction by the induced electric field make ionization collision with molecules or atoms of the etching gas (the NF₃ gas in the present embodiment), whereby a donut-shaped plasma is generated. Radicals in this donut-shaped plasma isotropically move and pass through the partition plate 37, consequently reaching the substrate process space S. However, the ions in the plasma anisotropically move. Therefore, the ions are captured by the partition plate 37 and cannot reach the substrate process space S. Specifically, for example, the anisotropically moving ions collide with the plate-like member 43 and stay there. Even if the anisotropically moving ions pass through the respective slits 46, the ions collide with the plate-like member 44 and stay there. Therefore, the respective ions cannot pass through the partition plate 37. The “donut-shaped plasma” is not limited to ring-shaped plasma which is not distributed radially inward (central portion) of the annular RF antenna 40 but is formed only radially outward of the RF antenna 40. The “donut-shaped plasma” may include plasma which is also distributed radially inward of the annular RF antenna 40 so that the volume or density of the plasma at the radial outer side of the annular RF antenna 40 becomes larger than that at the radial inner side of the annular RF antenna 40.

In the substrate process space S, the F radicals (F* or NF₂*) transmitted through the partition plate 37 react with the NH₃ gas directly supplied to the substrate process space S, thereby generating NH₄F as an etchant. The NH₄F is adsorbed onto the surface of the wafer W so that the SiO₂ film on the surface of the wafer W and the etchant react with each other to generate AFS as a reaction product. At this time, the NH₄F generated from the F radicals (F* or NF₂*) in a high energy state is also in the high energy state. Therefore, the generation of AFS is promoted. As a result, the removal of the SiO₂ film is accelerated. In the process module 13, for the purpose of preventing deactivation of the F radicals (F* or NF₂*), all the portions with which the F radicals (F* or NF₂*) may come into contact are covered with a dielectric material, for example, quartz. In addition, the AFS generated by the COR process is sublimated and removed in the process module 13 that performs a PHT process on the wafer W.

Incidentally, the partition plate 37 is exposed to the plasma generated in the plasma generation space P. As described above, the plasma generated in the plasma generation space P has a donut shape. Therefore, in the partition plate 37, the colliding ions are distributed in a donut shape (circular ring-shape). For example, when the COR process is repeated, heat is accumulated in the partition plate 37 in a circular ring-shape. As a result, heat is radiated from the partition plate 37 toward the substrate process space S in a circular ring-shape.

Incidentally, the distribution of radicals is strongly influenced by the heat distribution. Therefore, when heat is radiated from the partition plate 37 toward the substrate process space S in a circular ring-shape, a deviation is generated in the distribution of radicals (F radicals (F* or NF₂*)) in the substrate process space S. As a result, the distribution of NH₄F which is an etchant also deviates. Thus, there is a possibility that the COR process cannot be uniformly performed on the wafer W.

In the present embodiment, in view of the foregoing, the process module 13 is provided with a heat shield plate 48 arranged to face the wafer W between the partition plate 37 and the wafer W and configured to block radiant heat (see FIG. 2).

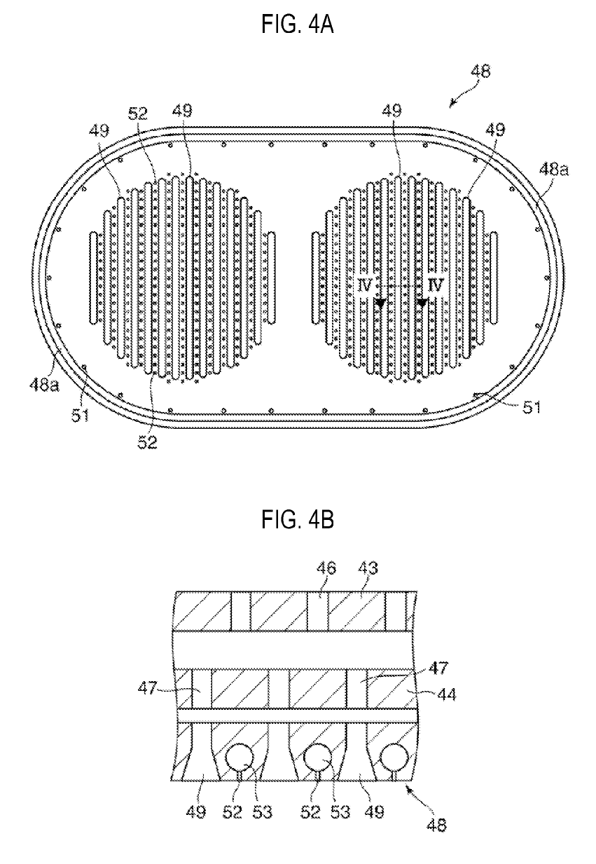

FIGS. 4A and 4B are views schematically showing the configuration of the heat shield plate in FIG. 2. FIG. 4A is a view of the heat shield plate as viewed from the substrate process space, and FIG. 4B is a sectional view taken along line IV-IV in FIG. 4A. In FIG. 4B, for the ease of understanding, the partition plate is also depicted.

As shown in FIGS. 4A and 4B, when viewed from the substrate process space S, the heat shield plate 48 has a substantially elliptical shape just like the plate-like members 43 and 44. The reason why the heat shield plate 48 has a substantially elliptical shape is that the horizontal sectional shape of the process container 28 has a substantially elliptical shape as shown in FIG. 1. The shape of the heat shield plate 48 is not limited to a substantially elliptical shape, but may vary depending on the horizontal sectional shape of the process container 28.

A plurality of slits 49 (radical passages) penetrating from the plasma generation space P toward the substrate process space S is formed in the heat shield plate 48. Each of the slits 49 is formed so as to correspond to each of the slits 47 of the plate-like member 44. In addition, the cross-sectional shape of each of the slits 49 increases in diameter from the plasma generation space P toward the substrate process space S. Instead of the slits 49, a plurality of through-holes increasing in diameter may be formed. The entire surface of the heat shield plate 48 including surfaces of the respective slits 49 is covered with a dielectric material, for example, a silicon or yttrium compound.

The heat shield plate 48 is made of a metal which is a material having a high thermal conductivity, for example, aluminum or aluminum alloy. When viewed from the substrate process space S, the heat shield plate 48 is formed to be larger than the plate-like member 44. A flange portion 48a constituting a peripheral portion of the heat shield plate 48 is embedded in the side wall portion 28a of the process container 28, thereby constituting a portion of the side wall portion 28a (see FIG. 2). In the process module 13, the heat shield plate 48 and the process container 28 above the heat shield plate 48 may be handled integrally. More specifically, the heat shield plate 48 and the process container 28 above the heat shield plate 48 may be integrally removed from the process container 28 below the heat shield plate 48.

Furthermore, in the heat shield plate 48, a large number of bolt holes 51 are formed along the flange portion 48a. The heat shield plate 48 is fastened to the process container 28 above the heat shield plate 48 by a large number of bolts (not shown) fitted into the bolt holes 51. Moreover, the heat shield plate 48 has a large number of gas ejection ports 52 arranged between the respective slits 49. The gas ejection ports 52 are distributed so as to face the wafer W and are connected to another gas supply source via the gas passage 53. In the present embodiment, for example, an NH₃ gas is ejected from the respective gas ejection ports 52 toward the substrate process space S (ultimately, the wafer W). In addition, a cooling mechanism 50, for example, a coolant flow path, a chiller or a Peltier element is embedded in the flange portion 48a constituting a portion of the side wall portion 28a.

In the process module 13, even if the COR process is repeatedly executed and heat is accumulated in the partition plate 37, it is possible to block the radiant heat from being transferred from the partition plate 37, in which heat is accumulated, to the wafer W, because the heat shield plate 48 disposed between the partition plate 37 and the wafer W is arranged to face the wafer W. Thus, it is possible to prevent occurrence of uneven distribution of radicals in the substrate process space S. As a result, even if the COR process is repeated, the COR process using radicals can be uniformly performed on the wafer W. Since the heat shield plate 48 constitutes a portion of the side wall portion 28a of the process container 28 and is fixed to the side wall portion 28a by the large number of bolts, it is possible for the heat shield plate 48 to efficiently transfer the heat radiated from the partition plate 37 to the process container 28. This makes it possible to prevent the heat from being accumulated in the heat shield plate 48. Furthermore, even if heat is annularly radiated from the partition plate 37, in which heat is accumulated in a circular ring-shape, toward the heat shield plate 48, it is possible to immediately transfer the radiated heat to the process container 28, because the heat shield plate 48 is made of a metal which is a material having high thermal conductivity. For example, it is possible to prevent heat from being annularly accumulated in the heat shield plate 48. In particular, both the heat shield plate 48 and the process container 28 are made of aluminum. Therefore, the heat shield plate 48 and the process container 28 easily conform to each other. This makes it possible to further improve the heat transfer from the heat shield plate 48 to the process container 28.

Since the heat shield plate 48 has a large number of gas ejection ports 52 distributed to face the wafer W, it is possible to eject the process gas (mainly the NH₃ gas) from the heat shield plate 48 toward the wafer W so as to be distributed substantially uniformly. As a result, the wafer W can be uniformly processed with an etchant generated from the NH₃ gas.

The heat shield plate 48 is spaced apart slightly from the plate-like member 44 by a spacer or the like (not shown). As a result, the heat shield plate 48 does not make contact with the plate-like member 44. This makes it possible to prevent the heat shield plate 48 and the plate-like member 44 from rubbing against each other due to the difference in thermal expansion amount between the heat shield plate 48 and the plate-like member 44, thereby preventing generation of particles.

The cross-sectional shape of each slit 49 increases in diameter from the plasma generation space P toward the substrate process space S. Therefore, even if the course of F radicals (F* or NF₂*) passing through each slit 49 is bent, it is possible to reduce the possibility that the F radicals (F* or NF₂*) collide with the heat shield plate 48. As a result, it is possible to reduce the possibility of deactivation of the F radicals (F* or NF₂*). Furthermore, the entire surface of the heat shield plate 48 including the surfaces of the respective slits 49 is covered with a dielectric material. Therefore, even if the F radicals (F* or NF₂*) collide against the heat shield plate 48, it is possible to reduce the possibility that the F radicals (F* or NF₂*) become deactivated. As a result, it is possible to prevent the COR process using the etchant generated from the F radicals (F* or NF₂*) from being stagnated due to the deactivation of the F radicals (F* or NF₂*). The entire surface of the heat shield plate 48 is covered with a dielectric material by a thermal spraying, CVD or the like.

Although the present disclosure has been described above using the above-described embodiments, the present disclosure is not limited to the above-described embodiments.

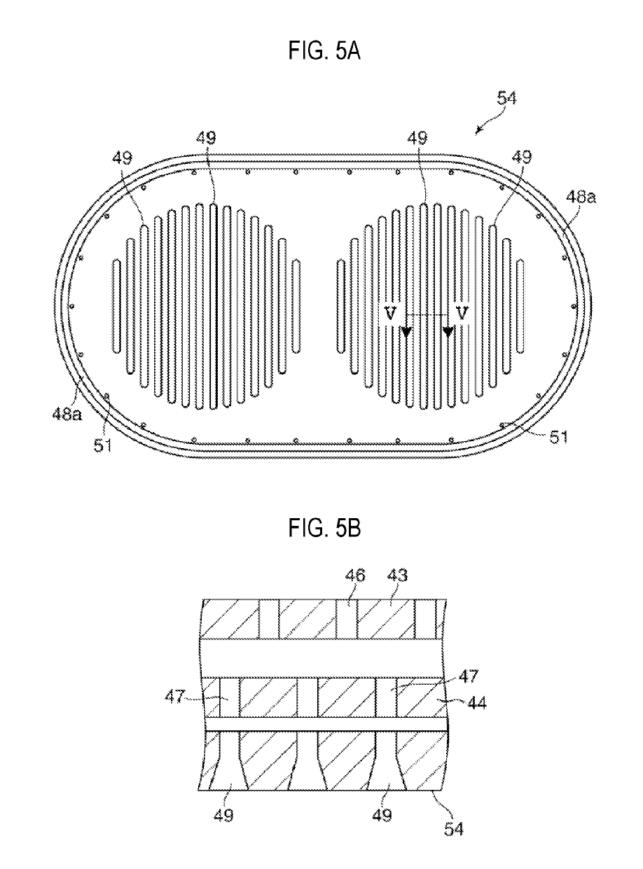

For example, although the heat shield plate 48 is made of a metal, it may be made of silicon having the same thermal conductivity as aluminum. In this case, as shown in FIGS. 5A and 5B, a heat shield plate 54 has a plurality of slits 49 and a plurality of bolt holes 51 formed therein just like the heat shield plate 48. Since silicon is a material that is hard-to-work, it is impossible to form the gas ejection ports 52 in the heat shield plate 54. Thus, the NH₃ gas is supplied to the substrate process space S from the gas introduction port formed in the side wall portion 28a facing the substrate process space S.

Although the flange portion 48a of the heat shield plate 48 constitutes a portion of the side wall portion 28a, the flange portion 48a of the heat shield plate 48 may not form a portion of the side wall portion 28a and may be connected to, for example, an engagement portion formed in the side wall portion 28a. In this case, in order to assure heat transfer between the engagement portion and the flange portion, the engagement portion and the flange portion may be fixed to each other by bolts or the like. In some embodiments, a heat transfer agent or the like may be filled between the engagement portion and the flange portion.

Furthermore, in the above-described embodiments, there has been described a case where the present disclosure is applied to the process module 13 that executes the COR process. However, the present disclosure is applicable to any process module 13 that executes a process using radicals. For example, the present disclosure may be applied to a process module 13 that performs a film forming process on the wafer W using radicals.

### Example

Next, an example of the present disclosure will be described.

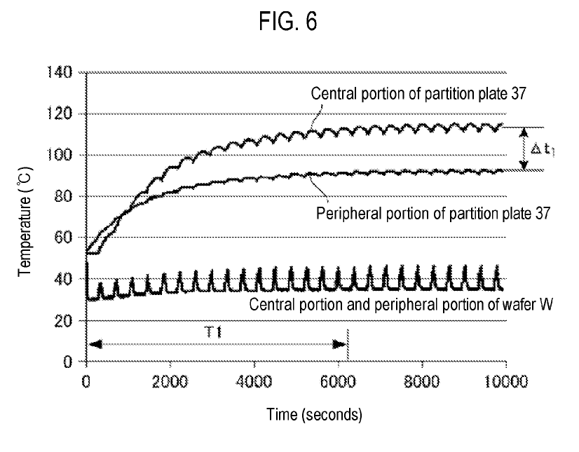

First, as a comparative example, the temperature of the central portion and the peripheral portion of the partition plate 37 and the temperature of the central portion and the peripheral portion of the wafer W were measured when a COR process is repeated in the process module 13 in which the heat shield plate 48 is not installed and the partition plate 37 directly faces the wafer W. At this time, the supply/non-supply of the high frequency power to the RF antenna 40 during the COR process was repeated at 1 minute/5 minutes. A time-dependent change in the measured temperature is shown in FIG. 6.

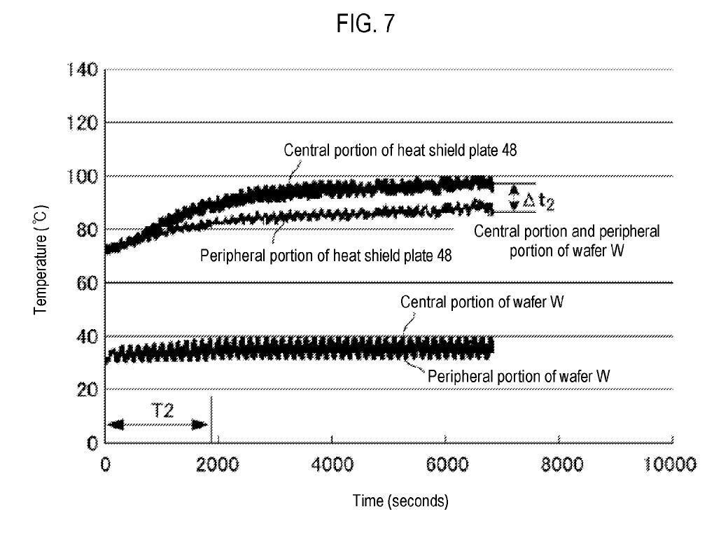

Next, the temperature of the central portion and the peripheral portion of the partition plate 37 and the temperature of the central portion and the peripheral portion of the wafer W were measured when a COR process is repeated in the process module 13 in which the heat shield plate 48 is installed and the heat shield plate 48 directly faces the wafer W. At this time, the supply/non-supply of the high frequency power to the RF antenna 40 during the COR process was repeated at 1 minute/1 minute. A time-dependent change in the measured temperature is shown in FIG. 7.

As shown in the graphs of FIGS. 6 and 7, it was confirmed that the temperature in the central portion of the heat shield plate 48 is lower than the temperature in the central portion of the partition plate 37 and further that a temperature difference Δt₂ between the central portion and the peripheral portion of the heat shield plate 48 is smaller than a temperature difference Δt₁ between the central portion and the peripheral portion of the partition plate 37. Presumably, this is because the heat shield plate 48 is made of a metal having a high thermal conductivity and the heat radiated toward the heat shield plate 48 is immediately transferred toward the process container 28, thereby suppressing an increase in temperature of the heat shield plate 48 and eliminating the deviation in heat distribution in the heat shield plate 48. Thus, it was found that the installation of the heat shield plate 48 can improve the heat distribution in the substrate process space S and can prevent occurrence of a deviation in radical distribution in the substrate process space S.

It was also found that a stabilization time T2 of the temperature of the wafer W in the case where the heat shield plate 48 is installed is shorter than a stabilization time T1 of the temperature of the wafer W in the case where the heat shield plate 48 is not installed. Presumably, this is because the temperature of the heat shield plate 48 has stabilized faster than the temperature of the partition plate 37 inasmuch as the radiated heat is immediately transferred toward the process container 28 and no heat is accumulated in the heat shield plate 48. Thus, it was found that the installation of the heat shield plate 48 makes it possible to execute a stable COR process from an early stage, thereby improving throughput.

According to the present disclosure, a heat shield plate which is disposed between a partition member for selectively transmitting radicals in plasma toward a substrate, and the substrate, is arranged to face the substrate. It is therefore possible to suppress heat from being radiated toward the substrate from the partition member in which heat is accumulated due to the repetition of the substrate process. This makes it possible to prevent a deviation in distribution of radicals from being generated in a process space facing the substrate. As a result, it is possible to uniformly subject the substrate to a radical-based process even when the substrate process is repeated. In addition, the heat shield plate is made of metal and is connected to a process container. Therefore, the heat shield plate can efficiently transfer the heat radiated from the partition member to the process container. This makes it possible to prevent heat from being accumulated in the heat shield plate.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus, comprising:
a process container configured to accommodate a substrate;
a partition member disposed between plasma generated inside the process container and the substrate, the partition member configured to selectively transmit radicals in the plasma toward the substrate; and
a heat shield plate disposed between the partition member and the substrate,
wherein the heat shield plate is disposed so as to face the substrate, the heat shield plate being made of a metal and being connected to the process container.

2. The apparatus of claim 1, wherein the heat shield plate constitutes a portion of the process container.

3. The apparatus of claim 2, wherein both the heat shield plate and the process container are made of aluminum or an aluminum alloy.

4. The apparatus of claim 1, wherein the heat shield plate has a plurality of ejection ports formed therein to eject a process gas toward the substrate.

5. The apparatus of claim 1, wherein the heat shield plate has a radical passage penetrating in a thickness direction, the radical passage having a cross-sectional shape increasing in diameter toward the substrate.

6. The apparatus of claim 1, wherein the heat shield plate is covered with a dielectric material.

7. The apparatus of claim 6, wherein the dielectric material is composed of a yttrium compound or silicon.

8. A substrate processing apparatus, comprising:
a process container configured to accommodate a substrate;
a partition member disposed between plasma generated inside the process container and the substrate, the partition member configured to selectively transmit radicals in the plasma toward the substrate; and
a heat shield plate disposed between the partition member and the substrate,
wherein the heat shield plate is disposed so as to face the substrate, the heat shield plate being made of silicon and being connected to the process container.

9. A heat shield plate disposed between a partition member, which is disposed between plasma and a substrate and configured to selectively transmit radicals in the plasma toward the substrate, and the substrate, wherein the heat shield plate is disposed so as to face the substrate, and the heat shield plate is made of a metal.

10. A heat shield plate disposed between a partition member, which is disposed between plasma and a substrate and configured to selectively transmit radicals in the plasma toward the substrate, and the substrate, wherein the heat shield plate is disposed so as to face the substrate, and the heat shield plate is made of silicon.
